(19) United States
(12) Patent Application Publication
(10) Pub. No.: US 2026/0310266 A1
(43) Pub. Date: Oct. 8, 2026

(54) Computer Case

(71) Applicant: Minilith, LLC, Pasadena, TX (US)

(72) Inventors: Janey RIZVI, Pasadena, TX (US); Atif IKBAL, Houston, TX (US)

(21) Appl. No.: 19/482,039

(22) PCT Filed: May 10, 2024
(86) PCT No.: PCT/US2024/028784

§ 371 Date: Nov. 6, 2025

Related U.S. Application Data
(60) Provisional application No. 63/466,217, filed on May 12, 2023.

(51) Int. Cl. G06F 1/18; F21V 17/10; F21V 23/00; F21V 23/06; F21Y 115/10; G06F 1/186; G06F 1/187; G06F 1/188; G06F 1/20; H05B 47/105; H05K 5/02; H05K 7/20

(52) U.S. Cl. CPC G06F 1/182; F21V 17/105; F21V 23/006; F21V 23/06; G06F 1/186; G06F 1/187; G06F 1/188; G06F 1/20; H05B 47/105; H05K 5/0247; H05K 7/20145; H05K 7/20172; H05K 7/20209; F21Y 2115/10; G06F 2200/201

(57) ABSTRACT

A computer case includes a left section including at least one removable left cover and at least one removable left panel. Each left panel includes a removable left modular insert. The computer case further includes a right section including at least one removable right cover and at least one removable right panel. Each right panel includes a removable right modular insert.

### CROSS-REFERENCE TO RELATED APPLICATIONS

This application claims the benefit of U.S. Provisional Application No. 63/466,217 filed May 12, 2023 and titled “Computer Case” by Janey RIZVI and Atif IKBAL.

### BACKGROUND

Current computer cases have numerous issues with regard to heating, connectivity, and aesthetics. First, graphics cards are not only increasing in size but heat generation as well. Attempts to ameliorate this issue with fans and fluid cooling systems only increase the noise produced, put the internal components at risk of damage due to exposure to cooling fluids, and use additional power. Next, the internal components and case itself cause electromagnetic interference with wireless communications such as Wi-Fi, Bluetooth, and the like if not outright blockage of these signals. Finally, current computer cases are inadequately customizable and responsive to user aesthetic preferences over time, making them unappealing and in need of replacement within a short period of time. When customizability is address, the implementations reduce the stability and integrity of the case as well as introduce cabling problems as a result.

### SUMMARY

A computer case includes a left section including at least one removable left cover and at least one removable left panel. Each left panel includes a removable left modular insert. The computer case further includes a right section including at least one removable right cover and at least one removable right panel. Each right panel includes a removable right modular insert.

A computer case includes a chassis including a front section. The computer case further includes a space within the chassis reserved for a graphics printed circuit board (“PCB”). The computer case further includes a space within the chassis reserved for a power supply unit (“PSU”) at the bottom and rear of the chassis below the space reserved for the graphics PCB. The computer case further includes an air ramp coupled to the front section at the bottom and front of the chassis. The air ramp is angled upward from horizontal such that air flowing through the front section is angled upward by the air ramp into the space reserved for the graphics PCB above the space reserved for the PSU.

A method of providing a computer case includes providing a left section including at least one removable left cover and at least one removable left panel. Each left panel includes a removable left modular insert. The method further includes providing a right section including at least one removable right cover and at least one removable right panel. Each right panel includes a removable right modular insert.

### BRIEF DESCRIPTION OF THE DRAWINGS

Accordingly, computer cases and methods for providing computer cases are disclosed herein. In the drawings:

FIG. 1 is an exploded rear perspective view of a computer case in at least one illustrated embodiment;

FIG. 2 is an exploded perspective view of bottom panels, inserts, and a cover of a computer case in at least one illustrated embodiment;

FIG. 3 is an exploded perspective view of front panels, inserts, and covers of a computer case in at least one illustrated embodiment;

FIG. 4 is an exploded perspective reverse view of right panels, inserts, and covers of a computer case in at least one illustrated embodiment;

FIG. 5 is a detail view of a pin connector of a computer case in at least one illustrated embodiment;

FIG. 6 is a detail view of a magnetic connector of a computer case in at least one illustrated embodiment;

FIG. 7 is a rear perspective view of a computer case in at least one illustrated embodiment;

FIG. 8 is a front perspective view of a computer case in at least one illustrated embodiment; and

FIG. 9 is a flow diagram of a method of providing a computer case in at least one illustrated embodiment.

It should be understood, however, that the specific embodiments given in the drawings and detailed description thereto do not limit the disclosure. On the contrary, they provide the foundation for one of ordinary skill to discern the alternative forms, equivalents, and modifications that are encompassed together with one or more of the given embodiments in the scope of the appended claims.

### NOTATION AND NOMENCLATURE

Certain terms are used throughout the following description and claims to refer to particular system components and configurations. As one of ordinary skill will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to.”.

### DETAILED DESCRIPTION

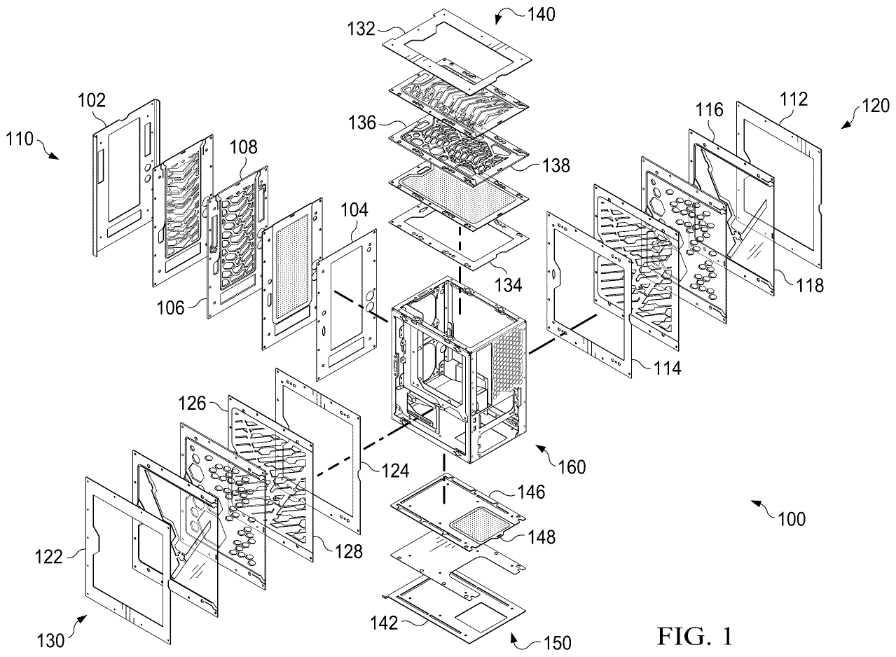

Computer cases and methods of providing computer cases are disclosed herein in various embodiments. FIG. 1 is an exploded rear perspective view of a computer case 100 in at least one embodiment. The case includes a front section 110, left section 120, right section 130, top section 140, bottom section 150, and back section 160. The front section 110 includes removable front covers 102, 104, removable front panels 106, and removable modular inserts 108. Similarly, the left section 120 includes removable left covers 112, 114, removable left panels 116, and removable left modular inserts 118; the right section includes removable right covers 122, 124, removable right panels 126, and removable right modular inserts 128; the top section 140 includes removable top covers 132, 134, removable top panels 136, and removable top modular inserts 138; and the bottom section 150 includes a removable bottom cover 142, removable bottom panels 146, and a removable bottom modular insert 148. In at least one embodiment, each bottom removable panel 146 includes a removable modular insert 148, and the panels are sandwiched by the two bottom covers 142. As shown, the bottom section 150 only includes one cover 142, and one of the panels 146 does not include a modular insert.

Each left insert 118 is interchangeable with other left inserts 118 and right inserts 128 (and vice versa) in at least one embodiment. Similarly, each top insert 138 is interchangeable with other top inserts 138 and front inserts 108 (and vice versa) in at least one embodiment. Accordingly, economies of scale may be realized and passed to the end user, and the configurable customizable inserts may meet the user's aesthetic preferences. As shown, the inserts removably couple to the panels via insertion. Specifically, the outer edges of three sides of the inserts engage with three inner edges of the panels such that the former slides into and out of the latter via the open edges of the panels. Such a configuration allows custom made inserts to be inserted into the panels for various user needs such as dust filtration, artwork and decorative patterns, lighting, and the like. As shown, two front inserts 108 are decorative while the third is for filtration. Similarly, two top inserts 138 are decorative while the third is for filtration. The singular bottom insert 148 is for filtration, and all the left 118 and right inserts 128 are decorative. If needed, for example, one decorative front insert 108 may be swapped for an additional filtration insert. As another example, if no filtration is needed in the top section 120, the top filtration insert 138 may be swapped for a third decorative insert. Swapping inserts is as easy as removing the initial cover without tools, as described below, removing the desired panel, sliding the insert out of the panel, sliding the new insert into the panel, and replacing the panel and cover (again without tools). As such, the entire process can be completed without using screws or a screwdriver, making frequent customization possible.

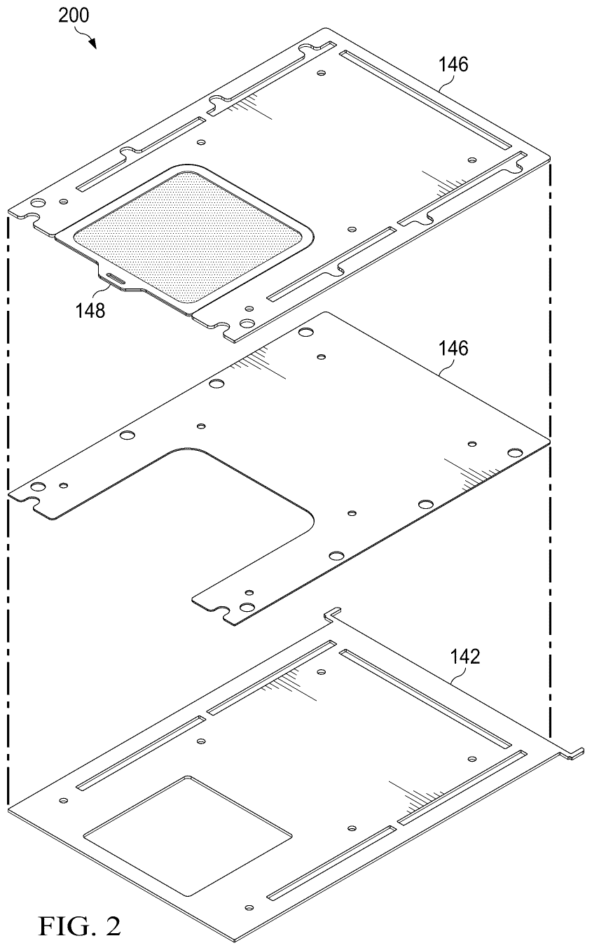

FIG. 2 is an exploded perspective view of a bottom assembly 200 including the bottom panels 146, an insert 148, and a cover 142 in at least one illustrated embodiment. As shown, the insert 148 is a filtration insert. However, it may be swapped for a decorative insert, and insert that provides stability to the case, and insert that enables placement of a fan, and insert containing a fan, an insert that accommodates cables and ease of cabling, or simply a solid metal insert for additional case integrity. The panels 146 and cover 142 include holes and cutouts to allow cabling, fasteners, light emitting diodes (“LEDs”), light, and air through the bottom section.

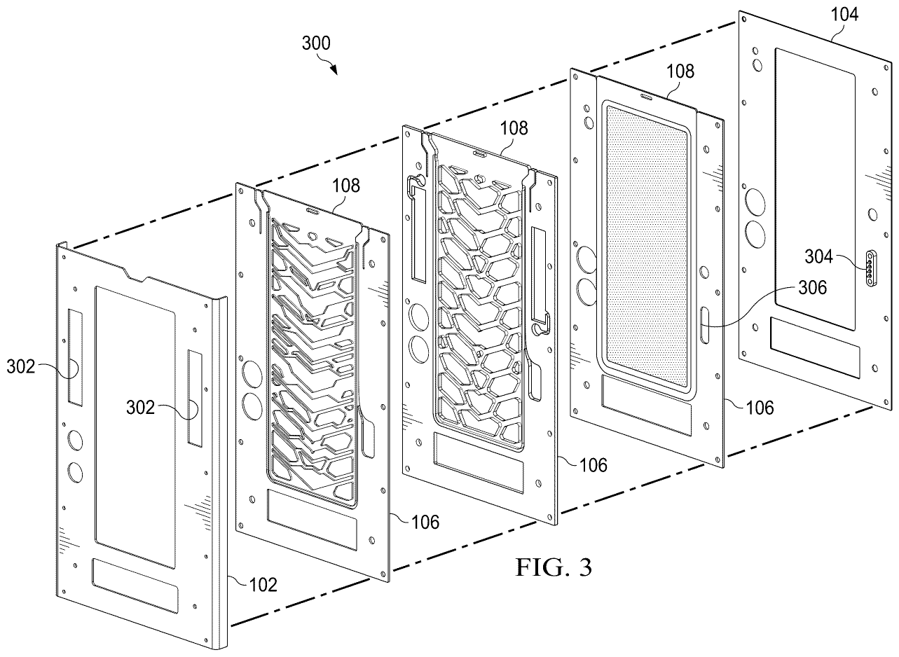

FIG. 3 is an exploded perspective view of a front assembly 300 including front panels 106, inserts 108, and covers 102, 104 in at least one embodiment. The outer front cover 102 and middle panel 106 includes cutouts 302 for an integrated antennas. The three panels 106 includes cutouts 306 for a pogo pin assembly 304 included on the inner cover 104. As such, when the front assembly 300 is collapsed, the pogo pin assembly 304 extends through the cutouts providing a reliable electric coupling to each panel 106. In at least one embodiment, an insert is used to provide lighting. Specifically, the insert may be made of a transparent or translucent illuminable material. Electroluminescent materials produce light when an electric current is passed through them, and neon uses electric current through a gas to produce a bright, colorful light. The pogo pin assembly 304 may power illumination of the illuminable inserts 108 in at least one embodiment. In another embodiment, the pogo pin assembly 304 may power lighting means, such as LED strips, which are inserted into the case. When lit, the light from the LED strips enters into the decorative inserts 108 causing them to glow. In various embodiments, the panels 106 are lit from one, two, three, or four sides by the LED strips.

Using either illumination method, when installed, the covers 102, 104 are imparted with a glowing outlines, and such glow is imparted to the cutouts as well as the internal components of the case 100. Different colors of light may impart different colors to the inserts and different inserts themselves may exude different colors of light. Additionally, the illuminable inserts may include cutouts, designs, or decorations that form pictures or words. In this way, glowing pictures, designs, or words may be used for each cover of the case according to user preference, and quickly changing preferences may be accommodated via the ease of cover, panel, and insert removal, replacement, and reinstallation. The panels 106 may also be configured to accept a three-dimensionally printed insert. As such, users may customize the case using their own printed inserts.

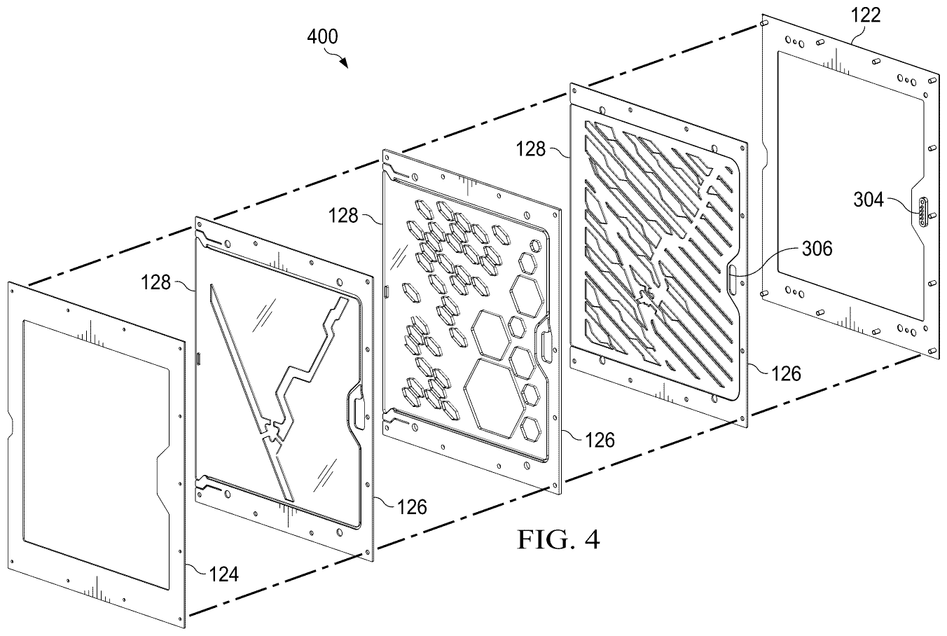

FIG. 4 is an exploded perspective reverse view of a left assembly 400 including left panels 126, inserts 128, and covers 122, 124. Similar to the front assembly, the left assembly 400 includes a pogo pin assembly 304 and cutouts 306 that allow the pogo pin assembly 304 to electrically couple to the panels 126 and inserts 128, thus illuminating them. Each cover pair, whether front, left 122, 124, right, top, or bottom, may sandwich zero, one, two, three, or more panels. The panels and inserts may be made of various materials including metal, tempered glass, acrylic, wood, or plastic in different embodiments according to need. For example, for dust filtration purposes, the inserts may include a solid plastic border surrounding a mesh design that captures dust. For decorative purposes, the inserts may be a solid acrylic material throughout to accept designs. Accordingly, the inserts may be solid in color, include various degrees of opacity, or be completely clear. The panels 126 may include cutouts through which pegs on the covers 122, 124 enter when collapsed to provide stability to the left assembly 400.

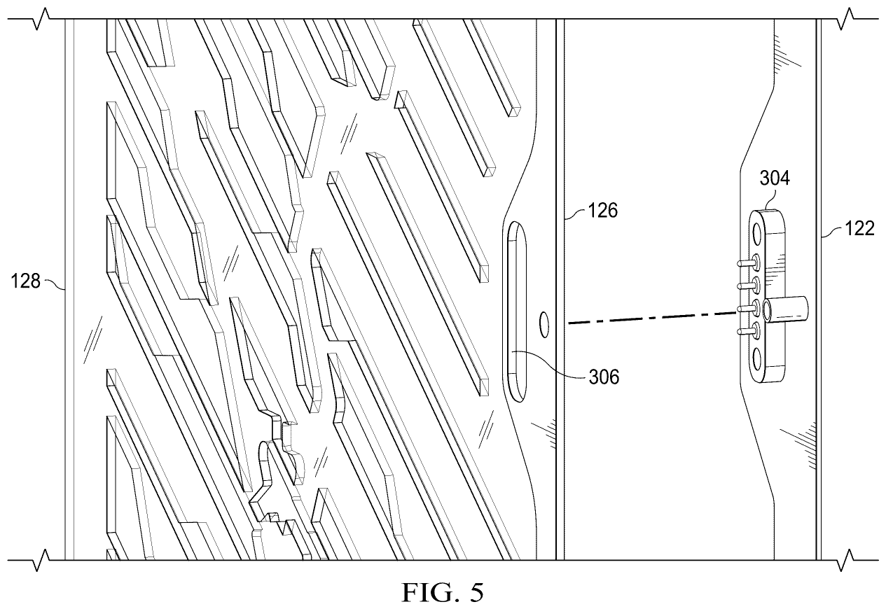

FIG. 5 is a detail view of a pogo pin assembly 304. Specifically, in order to power and connect the lighting, the LED strips, the covers, the panels, and/or the chassis, a pogo pin assembly 304 may be used. The pogo pin assembly 304 establishes an electrical connection between two components via one or more cylindrical bodies made of metal, one or more springs inside the bodies, and one or more small metal contact points at the end of the springs. The contact points may be made of a hard, durable metal like gold or tungsten, which provides a reliable, low-resistance connection. When the pins are pressed against a conductive surface, the springs inside the pins compress, allowing the contact points to make contact with the surface. The spring force ensures that the contact points maintain a consistent level of pressure against the surface, which helps to ensure a reliable and consistent electrical connection. When pressure is released, the springs return the pins to their original position, breaking the electrical connection.

As illustrated, male and female pogo pin connectors may be installed in the panels and main body of the chassis. When brought together, the connectors mate with each other through the cutouts 306 providing both a physical and electrical connection that secures the covers and panels and transfers energy to, e.g., the LED strips or illuminable inserts directly. The pogo pin assembly 304 obviates the need for cabling which is cumbersome and prone to tearing. Specifically, cabling must be disconnected prior to removal of the panels and/or covers, but the panels and/or covers themselves interfere with easy disconnection. In this way, panels and covers can be completely removed without the risk of a cable being damaged or prematurely disconnected.

For example, a power supply may output power to a pin on a motherboard, and the pogo pin assembly 304 on the inside cover 122 may be coupled to such pin. When mated with the opposing pogo pin assembly installed onto the outside cover, a complete circuit may be formed to power the LED strip or illuminable inserts. When a user desires to change the insert 128, rather than disconnecting a cable, the user may simply remove the outside cover, thus unmating the two pogo pin assemblies. Upon changing the insert 128, by sliding an insert out of a panel 126 and sliding another insert into the panel 126, the user may simply connect the cover by mating the two pogo pin assemblies again, providing power to the new insert. In this way, illuminable decorative panels may be easily changed as often as the user desires without cumbersome cabling. Dust filtration inserts and other types of inserts may be changed with similar ease.

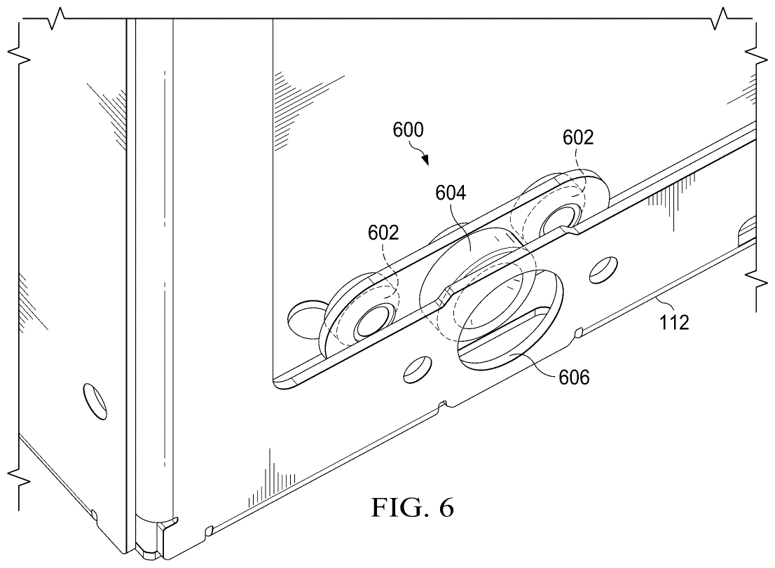

FIG. 6 is a detail view of a magnetic connector assembly 600. For further security, without impeding ease of access, magnetic connectors 602, 604 may be used to secure the covers 112 and panels. Specifically, the chassis and/or panel may include one or more magnetic elements, such as small magnets or ferromagnetic materials, while the cover and/or panel may include corresponding magnetic elements positioned to match the ones on the chassis. When the cover is brought close to the chassis, the magnetic elements align, and the magnetic force pulls them together through cutouts 606 on the panels and covers, creating a secure connection. This alignment ensures that the cover 112 is in the correct position relative to the chassis. To detach the cover 112 from the chassis, the user only needs to pull the cover 112 away from the chassis, and the magnetic force will release, allowing for easy removal without tools, such as a screwdriver, or fasteners, such as screws. These connector assemblies 600 provide a more robust and reliable connection than others, as there are no moving parts, and the connection is not easily disturbed by vibration or shock. Additionally, the shape of the magnetic connector assembly 600 allows for physical stability in addition to magnetic stability. That is, the cover 112 physically rests on the magnetic connector assembly 600, enabling increased stability without impeding access. Similar to FIG. 6, magnetic connector assemblies, may be used on any portion of the case 100 including to secure the front covers, left covers, right covers, top covers, and bottom covers to the front, left, right, top, and bottom portions of the chassis, respectively.

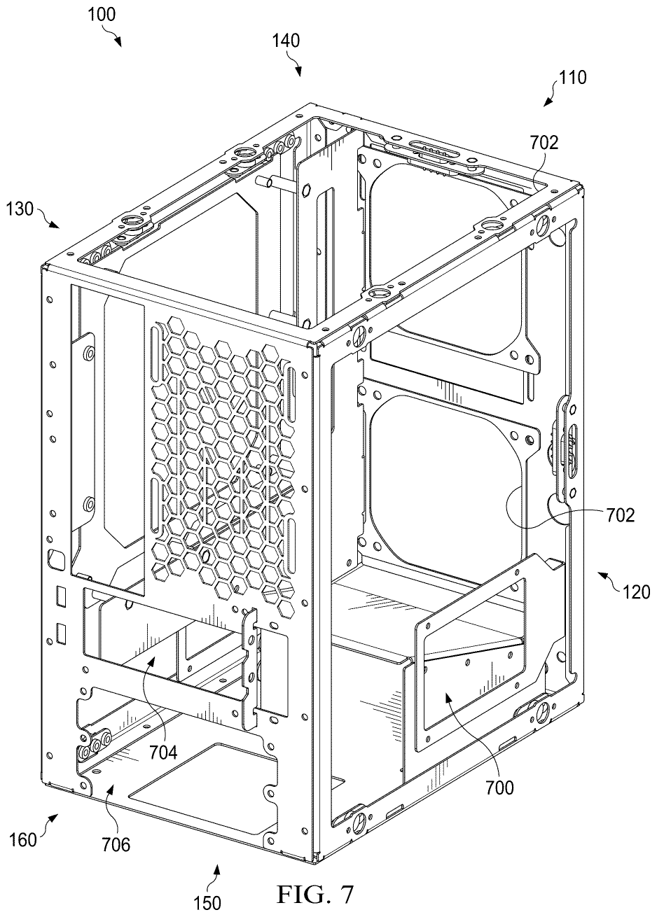

FIG. 7 is a rear perspective view of a computer case 100 in at least one embodiment. Front fans installed in the cutouts 702 of the chassis bring in cool air from the front of the case 100 to the components inside. Traditionally, fans dissipate air throughout the case 100 with the assumption that every portion inside the case 100 needs the same amount of cooling. However, in modern applications certain areas of the case 100 require more cooling than others. For example, the area inside the case 100 containing the graphics card (a printed circuit board including a graphics processor) may need the most cooling. As such, the case 100 includes an air ramp 700. Specifically, the chassis includes a front section 110 and a space within the chassis reserved for a graphics printed circuit board (“PCB”) 704. The case 100 further includes a space within the chassis reserved for a power supply unit (“PSU”) 706 at the bottom and rear of the chassis below the space reserved for the graphics PCB 704. In this way, the ramp 700 enables a very small footprint and component layout without sacrificing cooling. Additionally, the ramp 700 enables use of 92 mm fans rather than 120 mm fans, which enables an even smaller footprint.

The air ramp 700 is coupled to the front section 110 at the bottom and front of the chassis, and the air ramp 700 angled upward from horizontal such that air flowing through the front section 110 is angled upward by the air ramp 700 into the space reserved for the graphics PCB 704 above the space reserved for the PSU 706. The air ramp 700 may be angled upward by at least 30 degrees from horizontal. The front section 110 of the chassis may include a cutout 702 and attachment points, across from the air ramp 700, configured to enable a fan to be attached to the front section 110 and direct air onto the ramp 700. The cutout 702 and attachment points may enable a ninety-two millimeter fan to be attached to the front section 110 and direct air onto the ramp 700. Specifically, the air ramp 700 concentrates airflow from the front of the case 100 towards the air intake on the graphics card. Cool air that would have been dissipated, dispersed, or directed elsewhere instead travels along, and is directed by, the ramp 700 to cool the graphics card and graphics card area. In at least one embodiment, the angle of the ramp 700 is fixed and optimized to maximize airflow directed to the graphics card. In other embodiments, the angle of the air ramp 700 is variable and customizable.

In at least one embodiment, at least one of the front fans that provide air to the ramp 700 has its speed controlled by the motherboard. Specifically, sensors provide the motherboard with temperature information throughout the case 100, and the motherboard may automatically increase or decrease the speed of the fan to adjust to changing conditions. For example, the speed of the fan may be controlled by sending a variable voltage or pulse width modulation (PWM) signal to the fan, which causes the fan to spin faster or slower. In at least one embodiment, the motherboard may include a dedicated chip called a fan controller that can receive and interpret the signals from sensors and control the voltage or PWM signals sent to the fan accordingly. The fan controller may also adjust the fan speed based on other factors such as the workload of the central processing unit, graphical processing unit, or other components.

The air ramp 700 provides multiple benefits. First, it directs cooling air to where it is needed most. Second, it covers or obscures the power supply and cables, increasing the aesthetics of the case 100 and computer system. Third, it eliminates the need for liquid cooling solutions, which can be expensive, cumbersome, and dangerous to internal components. Fourth, it provides additional cooling without additional noise. Fifth, the ramp 700 reduces air turbulence inside the case 100 because, by directing airflow within the case 100, multiple currents of air do not interfere with each other. Sixth, the ramp 700 allows for a smaller chassis given the same amount of cooling capability. For example, without the ramp 700, the chassis would need to be taller to provide the same amount of cooling.

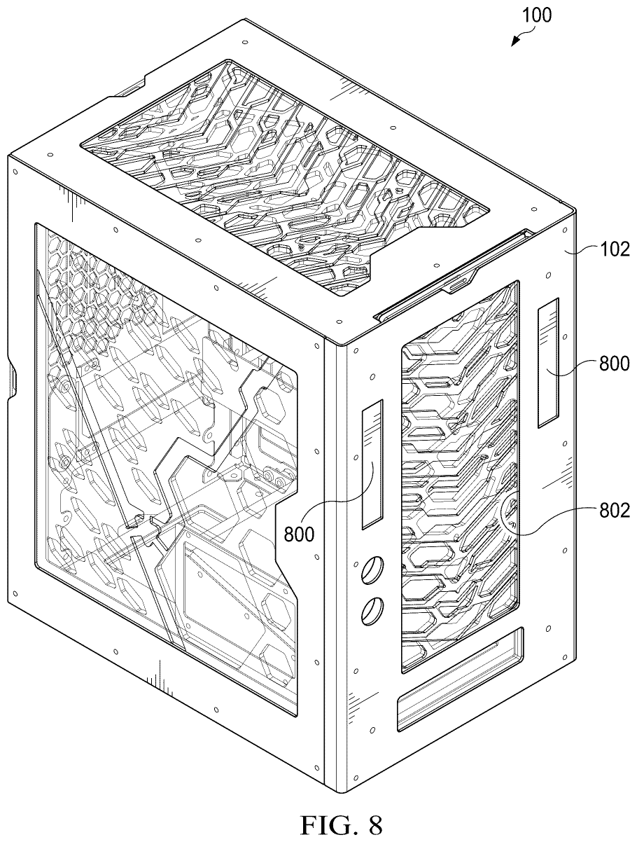

FIG. 8 is a front perspective view of a computer case 100 in at least one embodiment. The covers, panels, and inserts are collapsed, powered, and secured with pogo pin assemblies and magnetic connector assemblies. Additionally, modular omnidirectional antennas 800 are integrated into the case 100.

Computers use wireless signals, e.g. for protocols such as Wi-Fi and Bluetooth, to connect with peripheral devices such keyboards, mice, headphones, game controllers, and the like. However, the connections of these wireless signals are not strong. For example, game controllers often do not connect or lose connectivity only a few feet away from the case. Occasionally, motherboards include connectors for antennas that are attached externally. However, they either protrude from the case, causing integrity and aesthetic issues, or connect to the computer with a long wire, which increases the footprint of the system. However, the case 100 integrates two powerful antennas 800 on the outside front cover 102 to supply strong wireless signals without interference or blockage, thus enabling use of peripherals from a further distance. The antennas 800 are integrated into notched cutouts on the outside front cover 102 of the case 100 near the top and on either side of the large vertical cutout 802. The wire from the antennas 800 may run through a small hole in the case 100, and couple to the motherboard. The antennas 800 are modular so as protocols for wireless signals are updated, changed, and replaced, users can purchase new compatible antennas 800 and install them in the same case 100 thus increasing the life of the case.

There are many benefits to this implementation. First, the source of the wireless signals is strong, especially when compared to sources at the rear of the case 100 where, in addition to being further from peripherals, the case 100 itself may block or interfere with signals. Second, the integration with the case 100 increases the integrity of the antennas 800. Specifically, because they do not protrude from the case 100, stray movement will not damage or disconnect the antennas 800. Third, because long wires are eliminated, the footprint of the case 100 is decreased making it available for use in many more environments. Fourth, the aesthetic appeal of the case 100 is increased for the benefit of users. As shown, the case 100 provides a “best of both worlds” answer to the tradeoff between connectivity and integrity. That is, the antennas 800 are securely integrated into the case 100, but exposed to the air to send and receive strong wireless signals.

For cases with fixed ports, another impediment to customization and a driver of quick case replacement is that fixed ports cannot be separately repaired or upgraded. This causes inconvenience to users who need to replace or upgrade certain ports that have become damaged or no longer meet their needs due to advancing port standards. A common solution is to buy a new case, which is costly and time-consuming. Another solution is to use external ports which is unreliable and aesthetically unappealing. However, in at least one embodiment, the disclosed case 100 includes a 3.5 inch drive bay configured to accommodate a modular port assembly that is used to install any ports the user needs and upgradeable any time. In this way, users are not locked into a specific number or type of ports offered by the manufacturer. Rather users can replace, upgrade, and repair ports without buying a new case or using unreliable or unappealing external solutions.

In at least one embodiment, the case 100 includes a lighting controller (a dedicated PCB and processor) that adjusts illumination within the inserts and fan speeds in response to computer health, voice commands, computer sensor data, wireless input, and music. Specifically, the lighting controller may include a processor with logic and compute units, one or more sensors to detect case conditions such as heat, light, and the like, a wireless adapter and transceiver, volatile memory such as random access memory, non-volatile memory such as read-only memory, input ports such as analog inputs, microphone inputs and the like, LEDs, output ports such display ports and the like, a touch screen, inputs such as buttons and knobs, and data transfer ports such as USB ports. By using such a combination of hardware, in conjunction with appropriate software, much of the lighting, sensor, and fan computation may be offloaded onto the lighting controller rather than the motherboard. In this way, the case 100 produces little to no noise or interference with operation of the computer. Additionally, features such as dynamic lighting become possible. For example, the lighting of the case 100 may change based on the health of the operation of the computer. Red may denote poor health (e.g. high temperatures or overloaded processing), yellow for medium health, and green for a system with optimal health. Additionally, the lighting of the case 100 may change depending upon programs that are currently running (e.g. malicious programs, viruses, anti-virus programs). Next, the lighting of the case 100 may change based on the time and date (e.g. morning, evening, birthday, reminders). As a final example, the lighting of the case 100 may change based on a game or what is currently being displayed on a monitor connected to case 100 (e.g. the lighting may cease during dark moments of a game or movie, may turn red during a horror scene, and the like).

The lighting controller may be accessed via a mobile device via Bluetooth, Wi-Fi, or other wireless protocol. In at least one embodiment, users may download a customized application to their phone to control lighting profiles, turn their computer on or off, view real-time performance data such as temperatures, adjust cooling controls, and the like. The commands and data may also be integrated with voice assistants and lighting protocols already used by the user. To illustrate an example of the above, the user may command the voice assistant to turn on their computer by using verbal commands such as “[Voice Assistant], turn on my computer.” As another example, “Dim the lights” may integrate with the lighting controller to reduce the brightness of the LED strips within the case 100.

The lighting controller may be interchangeable between chassis. Specifically, if a user purchases a chassis as disclosed herein, the controller board and software may be transferred to the new chassis to control the instant lighting system as well. Furthermore, the same software may control multiple lighting controllers using a profile system should the user own multiple computers. Additionally, users may define and share macros that alter the default function of the software to create custom behavior that corresponds to their lighting and computer configuration. This community engagement lets users create, add, and share their own value to the system.

The case 100 may include a cable cover configured to aggregate and secure cables within the case 100, and the cable cover may include light emitting diodes that are adjusted by the lighting controller. Additionally, the lighting controller may include light emitting diodes that are adjusted by the lighting controller itself.

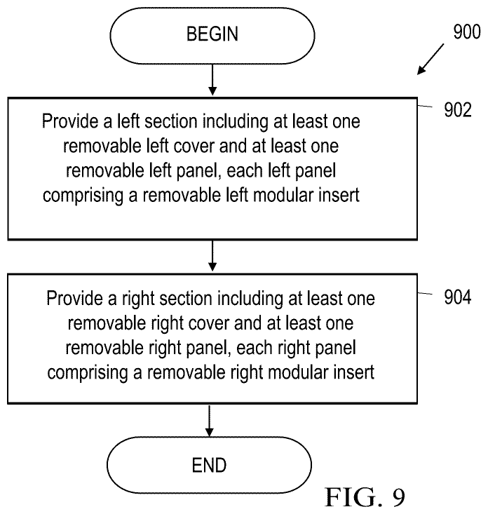

FIG. 9 is a flow diagram of a method 900 of providing a computer case in at least embodiment. In various embodiments, the method 900 includes providing any portions of the computer cases described above. At 902, a left section is provided, and it includes at least one removable left cover and at least one removable left panel. Each left panel includes a removable left modular insert. At 904, a right section is provided, and it includes at least one removable right cover and at least one removable right panel. Each right panel includes a removable right modular insert. In at least one embodiment, a front section is provided, and it includes at least one removable front cover and at least one removable front panel. Each front panel includes a removable front modular insert. A top section is provided in at least one embodiment, and it includes at least one removable top cover and at least one removable top panel. Each top panel includes a removable top modular insert. The left and right inserts are interchangeable, and the top and front inserts are interchangeable.

In the market for small form factor computers, maintenance and ease of component replacement is an afterthought to the dimensions of the case. However, the disclosed case 100 has been optimized for maintenance and upgrades without compromising on size. Specifically, the layout allows for easy cleaning and maintenance of components without requiring disassembly of the entire computer. Moreover, swapping out components can be performed with ease. For example, replacing the graphics card may be performed without removal or displacement of other components, and replacing the CPU may be performed without removing the mother board. This unique design ensures that small form factor computers are not only compact but also user-friendly and easy to upgrade. Additionally, when compared to other small form factor computers, the disclosed design offers a substantially smaller footprint. A smaller footprint plays a larger role in the small form factor market compared with other markets because small form factor cases are typically placed on desks, counters, tables, and the like.

Building a computer is a source of pride for many, and the disclosed case 100 allows showcase of hardware in a visually stunning way that other small form factor cases do not allow. That is, the disclosed case not only performs and functions well but also is a visual representation of a person's effort in building the hardware inside. For example, other cases obscure the installed hardware due to cables dispersed throughout the hardware. However, the disclosed layout provides for custom length cables that allow for the cables to be kept out of the way of the hardware in a rear area of the case. Such focus on cable management ensures that the hardware is showcased in an aesthetically pleasing and organized manner without compromising functionality.

In some aspects, apparatuses, systems, and methods are provided according to one or more of the following examples:

Example 1: A computer case includes a left section including at least one removable left cover and at least one removable left panel. Each left panel includes a removable left modular insert. The computer case further includes a right section including at least one removable right cover and at least one removable right panel. Each right panel includes a removable right modular insert.

Example 2: A computer case includes a chassis including a front section. The computer case further includes a space within the chassis reserved for a graphics printed circuit board (“PCB”). The computer case further includes a space within the chassis reserved for a power supply unit (“PSU”) at the bottom and rear of the chassis below the space reserved for the graphics PCB. The computer case further includes an air ramp coupled to the front section at the bottom and front of the chassis. The air ramp is angled upward from horizontal such that air flowing through the front section is angled upward by the air ramp into the space reserved for the graphics PCB above the space reserved for the PSU.

Example 3: A method of providing a computer case includes providing a left section including at least one removable left cover and at least one removable left panel. Each left panel includes a removable left modular insert. The method further includes providing a right section including at least one removable right cover and at least one removable right panel. Each right panel includes a removable right modular insert.

The following features may be incorporated into the various embodiments described above, such features incorporated either individually in or conjunction with one or more of the other features: The computer case may include a front section including at least one removable front cover and at least one removable front panel. Each front panel may include a removable front modular insert. The computer case may include a top section including at least one removable top cover and at least one removable top panel. Each top panel may include a removable top modular insert. The computer case may include a bottom section including at least one removable bottom cover and at least one removable bottom panel. Each bottom panel may include a removable bottom modular insert. Two left covers may sandwich at least two left panels, and each left insert may be interchangeable with other left inserts and the right insert. At least one front insert, left insert, right insert, and top insert may illuminate by reflecting light within them when the light enters them from other areas of the case. The computer case may include a lighting controller that adjusts illumination within the inserts and fan speeds in response to computer health, voice commands, computer sensor data, wireless input, and music. The lighting controller may be interchangeable between computer chassis. The lighting controller may include light emitting diodes that are adjusted by the lighting controller. The computer case may include a cable cover configured to aggregate and secure cables within the chassis. The cable cover may include light emitting diodes that are adjusted by the lighting controller. At least one front insert, left insert, right insert, and top insert may illuminate when electric current is passed through them. The computer case may include pogo pins that transfer electric current to the at least one front insert, left insert, right insert, and top insert when powered and mated. Such mating may occur when front, left, right, and top covers couple to the front, left, right, and top sections of the case respectively. The computer case may include magnetic connectors that secure the front covers, left covers, right covers, top covers, and bottom covers to the front, left, right, top, and bottom sections of the case, respectively, without separate fasteners such as screws. The left and right inserts may be interchangeable, and the top and front inserts may be interchangeable. The air ramp may be angled upward by at least 30 degrees from horizontal. The front section of the chassis may include a cutout and attachment points, across from the air ramp, configured to enable a fan to be attached to the front section and direct air onto the air ramp. The cutout and attachment points may enable a ninety-two millimeter fan to be attached to the front section and direct air onto the air ramp. The front section may include a first modular antenna integrated into a dedicated cutout on the left side of the front section. The front section comprises a second modular antenna integrated into a dedicated cutout on the right side of the front section. The front section may include a three-and-a-half inch drive bay configured to accommodate a modular port assembly. The method may further include providing a front section including at least one removable front cover and at least one removable front panel. Each front panel may include a removable front modular insert. The method may further include providing a top section including at least one removable top cover and at least one removable top panel. Each top panel may include a removable top modular insert. The left and right inserts may be interchangeable, and the top and front inserts may be interchangeable.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments in this disclosure have been described in terms of preferred embodiments, those skilled in the art will recognize that the embodiments herein can be practiced with modification within the spirit and scope of the embodiments as described herein. Numerous other modifications, equivalents, and alternatives, will become apparent once the above disclosure is fully appreciated. It is intended that the following claims be interpreted to embrace all such modifications, equivalents, and alternatives where applicable.

What is claimed is:

1. A computer case comprising:
a left section comprising at least one removable left cover and at least one removable left panel, each left panel comprising a removable left modular insert; and
a right section comprising at least one removable right cover and at least one removable right panel, each right panel comprising a removable right modular insert.

2. The computer case of claim 1, further comprising:
a front section comprising at least one removable front cover and at least one removable front panel, each front panel comprising a removable front modular insert;
a top section comprising at least one removable top cover and at least one removable top panel, each top panel comprising a removable top modular insert; and
a bottom section comprising at least one removable bottom cover and at least one removable bottom panel, each bottom panel comprising a removable bottom modular insert.

3. The computer case of claim 1, wherein two left covers sandwich at least two left panels, each left insert interchangeable with other left inserts and the right insert.

4. The computer case of claim 2, wherein at least one front insert, left insert, right insert, and top insert illuminate by reflecting light within them when the light enters them from other areas of the case.

5. The computer case of claim 4, further comprising a lighting controller that adjusts illumination within the inserts and fan speeds in response to computer health, voice commands, computer sensor data, wireless input, and music.

6. The computer case of claim 5, wherein the lighting controller is interchangeable between computer chassis.

7. The computer case of claim 5, wherein the lighting controller comprises light emitting diodes that are adjusted by the lighting controller.

8. The computer case of claim 5, further comprising a cable cover configured to aggregate and secure cables within the chassis, the cable cover comprising light emitting diodes that are adjusted by the lighting controller.

9. The computer case of claim 2, wherein at least one front insert, left insert, right insert, and top insert illuminate when electric current is passed through them.

10. The computer case of claim 9, further comprising pogo pins that transfer electric current to the at least one front insert, left insert, right insert, and top insert when powered and mated, such mating occurring when front, left, right, and top covers couple to the front, left, right, and top sections of the case respectively.

11. The computer case of claim 2, further comprising magnetic connectors that secure the front covers, left covers, right covers, top covers, and bottom covers to the front, left, right, top, and bottom sections of the case, respectively, without separate fasteners such as screws.

12. The computer case of claim 2, wherein the left and right inserts are interchangeable, and wherein the top and front inserts are interchangeable.

13. A computer case comprising:
a chassis comprising a front section;
a space within the chassis reserved for a graphics printed circuit board (“PCB”);
a space within the chassis reserved for a power supply unit (“PSU”) at the bottom and rear of the chassis below the space reserved for the graphics PCB; and
an air ramp coupled to the front section at the bottom and front of the chassis, the air ramp angled upward from horizontal such that air flowing through the front section is angled upward by the air ramp into the space reserved for the graphics PCB above the space reserved for the PSU.

14. The computer case of claim 13, wherein the air ramp is angled upward by at least 30 degrees from horizontal.

15. The computer case of claim 13, wherein the front section of the chassis comprises a cutout and attachment points, across from the air ramp, configured to enable a fan to be attached to the front section and direct air onto the air ramp.

16. The computer case of claim 15, wherein the cutout and attachment points enable a ninety-two millimeter fan to be attached to the front section and direct air onto the air ramp.

17. The computer case of claim 13, wherein the front section comprises a first modular antenna integrated into a dedicated cutout on the left side of the front section, and wherein the front section comprises a second modular antenna integrated into a dedicated cutout on the right side of the front section.

18. The computer case of claim 13, wherein the front section comprises a three-and-a-half inch drive bay configured to accommodate a modular port assembly.

19. A method of providing a computer case comprising:
providing a left section comprising at least one removable left cover and at least one removable left panel, each left panel comprising a removable left modular insert; and
providing a right section comprising at least one removable right cover and at least one removable right panel, each right panel comprising a removable right modular insert.

20. The method of claim 19, further comprising:
providing a front section comprising at least one removable front cover and at least one removable front panel, each front panel comprising a removable front modular insert; and
providing a top section comprising at least one removable top cover and at least one removable top panel, each top panel comprising a removable top modular insert;
wherein the left and right inserts are interchangeable, and wherein the top and front inserts are interchangeable.
